(19) United States
(12) Patent Application Publication
(10) Pub. No.: US 2010/0212585 A1
(43) Pub. Date: Aug. 26, 2010

(54) SUBSTRATE PROCESSING APPARATUS

(75) Inventor: Wataru Tsukinoki, Koshi City (JP)

Correspondence Address: CANTOR COLBURN, LLP, 20 Church Street, 22nd Floor, Hartford, CT, 06103, US

(73) Assignee: TOKYO ELECTRON LIMITED, Tokyo (JP)

(21) Appl. No.: 12/712,255

(22) Filed: Feb. 25, 2010

(30) Foreign Application Priority Data
Feb. 26, 2009 (JP) 2009-044566

(51) Int. Cl. B05C 13/00; H01L 21/677

(52) U.S. Cl. 118/500; 414/222.01

(57) ABSTRACT

Disclosed is a substrate processing apparatus for rapidly supplying a substrate from a carrier to a processing block. The carrier of which a wafer has been taken out is transferred from a wafer loading-in unit to an arrangement unit for retraction, a new carrier receiving a non-processed wafer is transferred to the wafer loading-in unit, a substrate holding unit for holding one hundred wafers in a shelf form is prepared when the wafer is supplied from the new carrier to a processing block, five wafers are collectively transferred by a second substrate transfer unit from the carrier to the substrate holding unit by a first substrate transfer unit, and then the wafers are transferred from the substrate holding unit to the processing block one by one. Five wafers are transferred to the substrate holding unit at a time, but the wafers are taken out of the substrate holding unit one by one. Accordingly, it is possible to rapidly supply the wafer without interruption in supplying the wafer to the processing block.

This application is based on and claims priority from Japanese Patent Application No. 2009-044566, filed on Feb. 26, 2009, with the Japanese Patent Office, the disclosure of which is incorporated herein in its entirety by reference.

### TECHNICAL FIELD

The present disclosure relates to a substrate processing apparatus for a substrate including a semiconductor wafer or an LCD substrate (a glass substrate for a liquid crystal display). The substrate processing apparatus performs a substrate processing, such as coating processing of a resist liquid or developing processing after exposure.

### BACKGROUND

A process for manufacturing a semiconductor device or an LCD substrate forms a resist pattern on a substrate using technology of photolithography. This technology employs a series of process of coating a resist liquid on a substrate, such as a semiconductor wafer (hereinafter, referred to as the wafer) to form a resist liquid film on a surface of the wafer, exposing the resist liquid film using a photo mask, and then performing a developing processing, thereby obtaining a desired pattern.

Such a processing is generally implemented using a resist pattern forming apparatus. In the resist pattern forming apparatus, an exposure apparatus is connected to a coating and developing apparatus that coats/develops the resist liquid. In the apparatus, as shown in FIG. 13, a carrier 10 receiving a plurality of wafers is loaded on a carrier stage 11 within a carrier block 1A and the wafer of carrier 10 is transferred to a processing block 1B by a transfer arm 12. Then, a resist film is formed on the wafer in a coating module 13 within a processing block 1B and the wafer is carried to an exposure apparatus 1D through an interface block 1C. In the meantime, the exposure processed wafer is returned to processing block 1B again to experience the developing process by a developing module 14, and then the wafer is returned to original carrier 10. Before or after the process of forming the resist film or the developing process, a heating process or a cooling process is performed for the wafer. A heating module or a cooling module is arranged on shelf modules 15A to 15C in a multi-stage. A heating module performs the heating process and a cooling module performs the cooling process. The wafer is carried between each module by main arms 16A and 16B mounted on processing block 1B.

In the resist pattern forming apparatus, the wafer is transferred by transfer arm 12 to processing block 1B one by one, and the wafer is carried between the modules by main arms 16A and 16B one by one in processing block 1B. At this time, as disclosed in Japanese Laid-Open Patent publication No. 2004-193597, when the above processing is performed, the wafer is carried according to a predetermined wafer transfer schedule. The wafer transfer schedule indicates that every wafer to be processed is carried to which module at which timing. Accordingly, transfer arm 12 and main arms 16A and 16B are associated with each other to transfer wafer W.

Conventionally, carrier 10 is given for every processing lot. The wafer provided from one carrier to processing block 1B experiences a predetermined processing in processing block 1B and exposure apparatus 1D. Then, the wafer is received in original carrier 10. At this time, a plurality of carriers 10, e.g. four carriers 10, are arranged on carrier stage 11. Transfer arm 12 can move forward and backward, ascend/descend, move in a Y direction of FIG. 13, and rotate around a vertical axis, thereby accessing every carrier 10. After supplying the wafer to processing block 1B, vacant carrier 10 stands by until a predetermined process for the wafer on carrier stage 11 is completed. After processing-completed wafer W is returned to carrier 10, the carrier receiving the processing-completed wafer is exchanged with a new carrier receiving a non-processed wafer.

Then, in order to improve the throughput, it is necessary to increase an operating rate of the apparatus, i.e. an operating rate of the processing module in processing block 1B. In this respect, the processing capability of processing block 1B has been recently improved, so that the throughputs of processing block 1B and exposure apparatus 1D are approximately 130 wafers/hour. Processing block 1B and exposure apparatus 1D can simultaneously process, e.g. 130 wafers, respectively. Therefore, the operating rate of the processing module tends to depend on a wafer W transfer capability by transfer arm 12 between processing block 1B. However, since transfer arm 12 transfers one wafer W at a time and accesses four carriers 10, a moving distance in an arrangement direction (Y direction) of carrier 10 is long and consequently a load of transfer arm 12 is large, thereby causing a difficulty in improving the transfer capability of wafer W more than the current condition. Therefore, if the throughput of processing block 1B or exposure apparatus 1D is further improved later, the wafer transfer capability by transfer arm 12 between processing block 1B cannot catch up with the improved throughput, thereby there being concerns on deteriorating the throughput improvement.

Meanwhile, in the conventional construction that vacant carrier 10 stands by on carrier stage 11 after supplying wafer W to processing block 1B, if carrier 10 receiving one wafer, such as a substrate for evaluation test, a substrate for research and development, and a substrate for manufacturing test, is carried, the total number of wafers to be supplied to processing block 1B decreases, and therefore, the operating rate of the processing module deteriorates.

Accordingly, the inventors of the present disclosure have considered that a stocker temporarily storing the carrier in addition to the carrier stage is installed. After the wafer is taken out of one carrier, the carrier is retracted to the stocker, a new carrier is arranged on the carrier stage, and then the wafer is taken out of the new carrier, so that the wafer is continuously supplied to the processing block from the carrier, thereby preventing the throughput deterioration.

In this case, in a view point of the throughput improvement, it is preferred that the operation of taking wafer W out of the carrier is performed during the exchanging of the vacant carrier of which the wafer has been taken out with a new carrier. Accordingly, it is considered that a plurality of carrier arrangement units is installed on the carrier stage, two or more carrier arrangement units among them are used as arrangement units for loading-in, on which the carrier supplying the wafer to the processing block is laid, and another two or more carrier arrangement units are used as arrangement units for loading-out, on which the carrier receiving the wafer from the processing block is laid. With respect to the carrier laid on the arrangement unit for loading-in, the other vacant carrier of which the wafer has been taken out is retracted to the stoker during taking the wafer out of one carrier, and then a new carrier of which the wafer is to be taken out in a next time is transferred to the arrangement units for loading-in.

Conventionally, twenty five wafers W are received in carrier 10. If carrier 10 is continuously transferred to carrier stage 11, it takes a certain of time until taking every wafer W out of carrier 10. Therefore, the vacant carrier of which the wafer is taken out can be exchanged with the new carrier within the time of taking out the wafer.

However, as described in the above, if carrier 10 receiving one wafer is carried, the time for taking wafer W out of carrier 10 is short. Therefore, the vacant carrier of which the wafer has been taken out cannot be exchanged with the new carrier within the time of taking out the wafer. As a result, a period for which wafer W cannot be taken out of the carrier may occur. In this case, even though the stocker is installed, it is impossible to continuously supply wafer W from the carrier to processing block 1B. Therefore, the operating rate of the processing module in processing block 1B and exposure apparatus 1D decreases, thereby deteriorating the throughput.

### SUMMARY

According to one embodiment, there is provided a substrate processing apparatus. The substrate processing apparatus includes a carrier receiving a plurality of substrates and an arrangement unit for transfer given for every carrier. The substrate processing apparatus processes substrates taken out of the carrier arranged on the arrangement unit for transfer one by one in a processing block, and then returns the substrate to an original carrier on the arrangement unit for transfer. The substrate processing apparatus includes a plurality of arrangement units for retraction to arrange the carrier, a carrier transfer unit, a substrate holding unit, a first substrate transfer unit, and a second substrate transfer unit. The plurality of arrangement units for retraction is separately installed from the arrangement unit for transfer. The carrier transfer unit transfers the carrier of which the substrate is taken out in the arrangement unit for transfer to the arrangement unit for retraction, and transfers a new carrier receiving non-processed substrate to the arrangement unit for transfer. The substrate holding unit holds a maximum number of substrates received by at least one carrier in a shelf form. The first substrate transfer unit includes a plurality of holding arms to hold the substrate so as to collectively receive a plurality of substrates from the carrier arranged on the arrangement unit for transfer and transfer the substrates to the substrate holding unit. The second substrate transfer unit receives the substrates from the substrate holding unit one by one and transfers the received substrate to the processing block.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view illustrating a resist pattern forming apparatus according to an embodiment of the present disclosure.

FIG. 2 is a perspective view illustrating the resist pattern forming apparatus.

FIG. 3 is a perspective view illustrating a carrier block of the resist pattern forming apparatus.

FIG. 4 is a perspective view illustrating the carrier block seen from a side of a processing block.

FIG. 5 is a front view illustrating the carrier block seen from a side of a carrier transfer unit.

FIG. 6 is a front view illustrating a carrier.

FIG. 7 is a perspective view illustrating a part of a substrate holding unit installed in the carrier block.

FIG. 8 is a plan and cross-sectional view illustrating a part of the substrate holding unit.

FIG. 9 is a cross-sectional view illustrating a part of the carrier block and processing block.

FIG. 10 is a view illustrating a part of a controller of the resist pattern forming apparatus.

FIGS. 11A to 11E are side views illustrating an operation of the resist pattern forming apparatus.

FIG. 12 is a plan view illustrating the resist pattern forming apparatus according to another embodiment.

FIG. 13 is a plan view illustrating a conventional resist pattern forming apparatus.

### DETAILED DESCRIPTION

In the following detailed description, reference is made to the accompanying drawings, which form a portion hereof. The illustrative embodiments described in the detailed description, drawings, and claims are not meant to be limiting. Other embodiments may be utilized, and other changes may be made, without departing from the spirit or scope of the subject matter presented here.

The present disclosure is to provide technology capable of rapidly supplying a substrate from a carrier to a processing block.

According to one embodiment, there is provided a substrate processing apparatus. The substrate processing apparatus includes a carrier receiving a plurality of substrates and an arrangement unit for transfer given for every carrier. The substrate processing apparatus processes substrates taken out of the carrier arranged on the arrangement unit for transfer one by one in a processing block, and then returns the substrate to an original carrier on the arrangement unit for transfer. The substrate processing apparatus includes a plurality of arrangement units for retraction to arrange the carrier, a carrier transfer unit, a substrate holding unit, a first substrate transfer unit, and a second substrate transfer unit. The plurality of arrangement units for retraction is separately installed from the arrangement unit for transfer. The carrier transfer unit transfers the carrier of which the substrate is taken out in the arrangement unit for transfer to the arrangement unit for retraction, and transfers a new carrier receiving non-processed substrate to the arrangement unit for transfer. The substrate holding unit holds a maximum number of substrates received by at least one carrier in a shelf form. The first substrate transfer unit includes a plurality of holding arms to hold the substrate so as to collectively receive a plurality of substrates from the carrier arranged on the arrangement unit for transfer and transfer the substrates to the substrate holding unit. The second substrate transfer unit receives the substrates from the substrate holding unit one by one and transfers the received substrate to the processing block.

According to one embodiment, a multiple number of the arrangement units for transfer may be installed. Further, the substrate holding unit holds processing-completed substrates after processing in the processing block. The second substrate transfer unit receives the processing-completed substrate one by one from the processing block and transfers the received substrate to the substrate holding unit. The first substrate transfer unit collectively receives the plurality of processing-completed substrates from the substrate holding unit and transfers the collectively received processing-completed substrates to the original carrier on the arrangement unit for transfer. Further, the carrier transfer unit transfers the original carrier corresponding to a lot to the arrangement unit for transfer, by the time the first substrate transfer unit receives the head of processing-completed substrates in the lot held in the substrate holding unit.

According to one embodiment, the substrate holding unit holds the non-processed substrate and holds the processing-completed substrate after processing in the processing block. The substrate holding unit may hold the substrates equal to or more than two times of a maximum number of the substrate received in one carrier, and in the first substrate transfer unit, a number of holding arms may be a divisor of a maximum number of substrates received in the carrier. Further, the first substrate transfer unit may include a first advance/retreat mechanism to advance/retreat one holding arm only and a second advance/retreat mechanism to collectively advance/retreat remaining holding arms.

According to one embodiment, the processing block includes a plurality of modules and a third substrate transfer unit so as to form a coating film on the substrate and develop the substrate after exposure. The plurality of modules processes the substrate or disposes the substrate thereon. The third substrate transfer unit transfers the substrate between the plural modules.

According to one embodiment, the carrier of which the wafer has been taken out in the arrangement units for transfer is transferred, a new carrier receiving a non-processed wafer is transferred, the substrate holding unit for holding a plurality of wafers in a shelf form is prepared when the wafer is supplied from the new carrier to a processing block, a plurality of wafers are collectively transferred by the first substrate transfer unit from the carrier to the substrate holding unit, and then the wafer is transferred by the second substrate transfer unit from the substrate holding unit to the processing block one by one.

Accordingly, the plural wafers are transferred to the substrate holding unit at a time, but the wafers are extracted from the substrate holding unit one by one. As a result, even when the carrier on the arrangement unit for transfer is exchanged, the substrate is held in the substrate holding unit. Therefore, in comparison with the case of transferring the substrate from the carrier to the processing block one by one, the substrate processing apparatus according to the embodiment can supply the substrate to the processing block without interruption. Further, even though the supply of the substrate is interrupted, it is possible to decrease the interruption time, so that the substrate can be rapidly supplied from the carrier to the processing block.

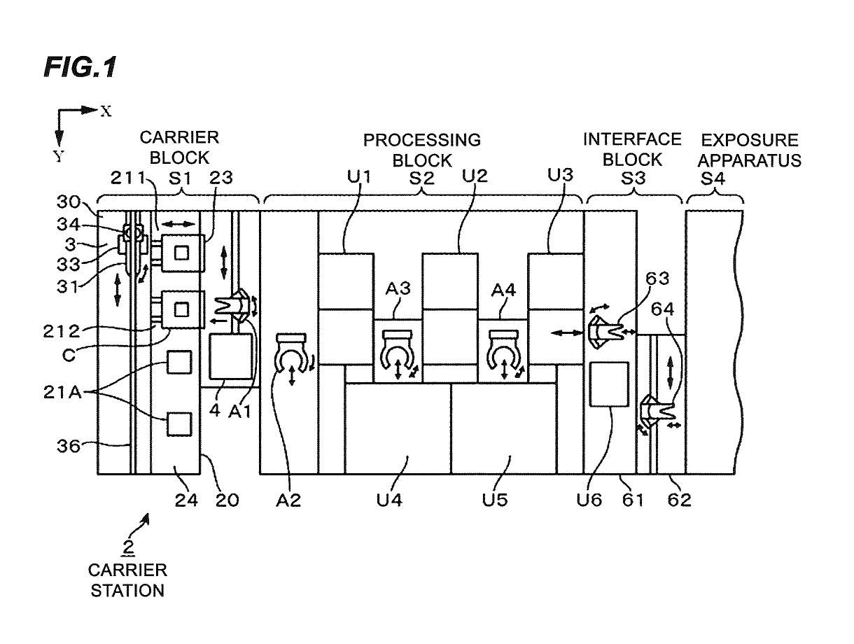

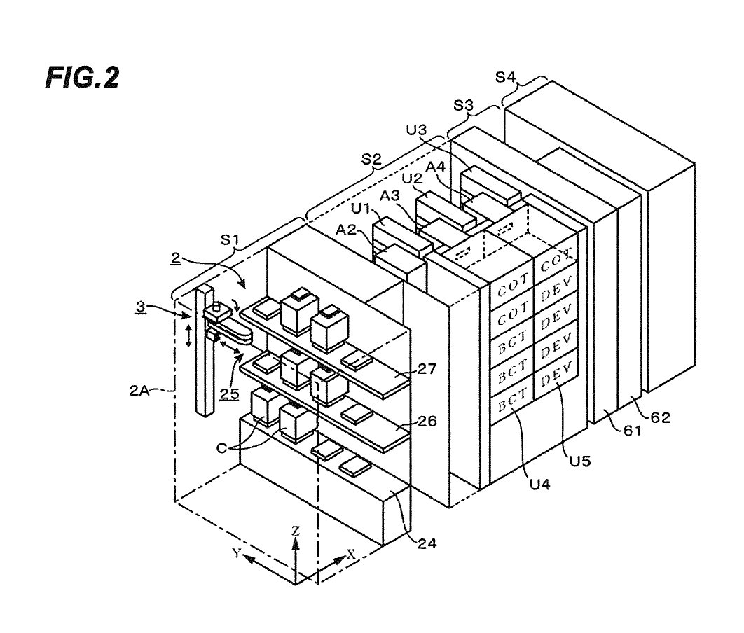

Hereinafter, the case where the substrate processing apparatus of the present disclosure is applied to a coating and developing apparatus is described as an example. First, the resist pattern forming apparatus will be described with reference to the drawings. In the resist pattern forming apparatus, the exposure apparatus is connected to the coating and developing apparatus. FIG. 1 is a plan view illustrating a resist pattern forming apparatus according to an embodiment of the present disclosure and FIG. 2 is a schematic perspective view illustrating the resist pattern forming apparatus according to an embodiment of the present disclosure. Referring to FIGS. 1 and 2, reference number S1 denotes a carrier block for loading-in/loading-out a carrier C. The carrier C receives maximum twenty five substrates, e.g. wafers W aritightly. Reference number S2 denotes a processing block for performing a coating and developing processing for wafer W, reference number S3 denotes an interface block, and reference number S4 denotes an exposure apparatus.

The Carrier block S1 includes a carrier station 2, a carrier transfer unit 3, a substrate holding unit 4, and a first substrate transfer unit A1. Arrangement units 21 (211 and 212) for transfer of carrier C and arrangement units 21 (221 to 228) for retraction of carrier C are installed in a multi-stage in carrier station 2. Carrier transfer unit 3 transfers the carrier between arrangement units 21 and 22 of carrier station 2. Substrate holding unit 4 holds the plurality of wafers W in a multi-stage. First substrate transfer unit A1 transfers the wafer W between carrier C laid on arrangement unit 21 for transfer and substrate holding unit 4. A peripheral of the carrier block S1 is enclosed by a case 2A. An opening/closing unit 23 is provided in a front wall side of carrier C arranged on arrangement unit 21 for transfer from a viewpoint of carrier station 2.

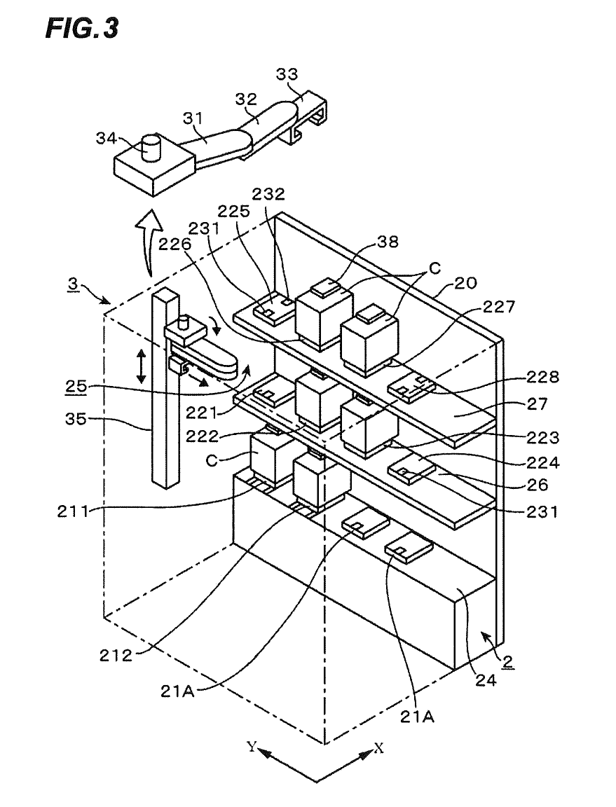

As shown in FIG. 3, carrier station 2 includes an arrangement stage 24 and a stocker 25. Arrangement units 21 (211 and 212) for transfer are installed in arrangement stage 24. A stocker 25 is installed in an upper side of arrangement stage 24 and serves as a storage unit to temporarily store carrier C. Stocker 25 includes shelves 26 and 27 installed in multiple stages, e.g. two stages. Two arrangement units 21 for transfer and two carrier C arrangement units 21A are installed on arrangement stage 24 and are arranged on arrangement stage 24 side by side in a Y direction of FIG. 1. The Carrier C arrangement unit 21A is an arrangement unit on which carrier C is laid when an operator directly loads in/out carrier C.

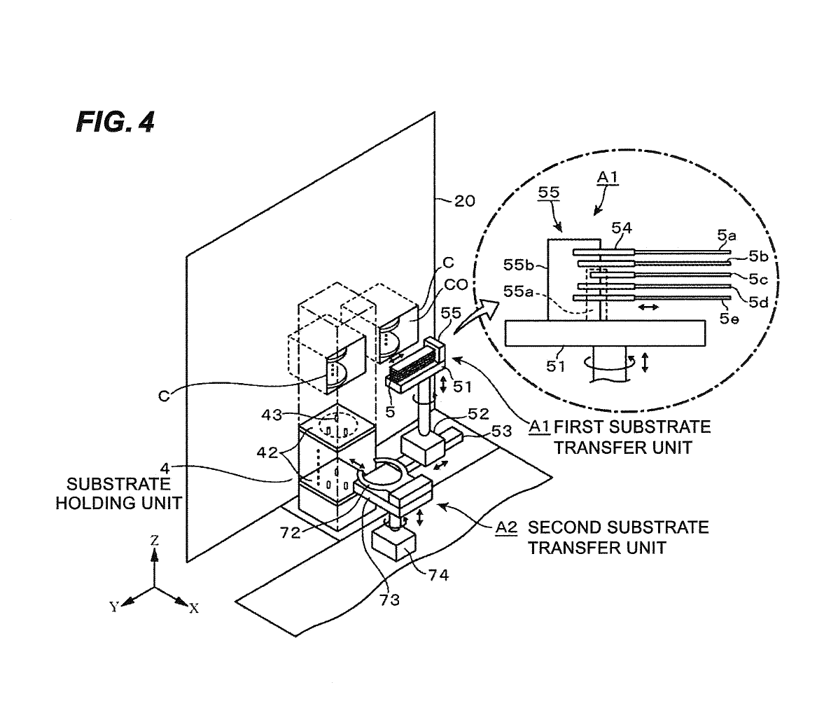

The arrangement unit 21 for transfer is given for every carrier C and serves as an arrangement unit which first substrate transfer unit A1 accesses. Carrier C to be arranged is fixed to the arrangement unit 21 for transfer. The arrangement unit 21 for transfer can slide in an X direction of FIG. 1. Further, a wafer extracting opening CO installed on carrier C (refer to FIG. 4) is connected to opening/closing unit 23. Accordingly, when opening/closing unit 23 is opened, wafer extracting opening CO is opened toward the rear of carrier station 2.

In the present embodiment, one arrangement unit 211 for transfer among arrangement units 211 and 212 for transfer on arrangement stage 24 is assigned as a wafer loading-in unit. Wafer loading-in unit supplies wafer W from carrier C to a processing block S2. Another arrangement unit 211 for transfer is assigned as a wafer loading-out unit. The wafer loading-out unit returns wafer W from processing block S2 into carrier C.

Further, plural arrangement units are arranged in the stocker 25. The arrangement unit is given for every carrier C. Carrier C is arranged to be temporarily stored on arrangement unit. In the present embodiment, the arrangement unit within stocker 25 also serves as arrangement unit 22 for retraction. With respect to arrangement unit 22 for retraction, a plurality of, e.g. four, arrangement units 221 to 224 for retraction are arranged on lower shelf 26 side by side in the Y direction within stocker 25, and a plurality of, e.g. four, arrangement units 225 to 228 for retraction are arranged on upper shelf 27 side by side in the Y direction within stocker 25.

Herein, among upper arrangement units 225 to 228 for retraction, two arrangement units 225 and 226 for retraction are used as carrier loading-in units. Carrier C is laid on the carrier loading-in unit when carrier C is loaded into the resist pattern forming apparatus from the outside. The other two arrangement units 227 and 228 for retraction are used as the carrier loading-out units. Carrier C is laid on the carrier loading-out unit when carrier C is loaded out from the resist pattern forming apparatus to the outside. Further, carrier C is arranged on and fixed to arrangement units 221 to 228 for retraction.

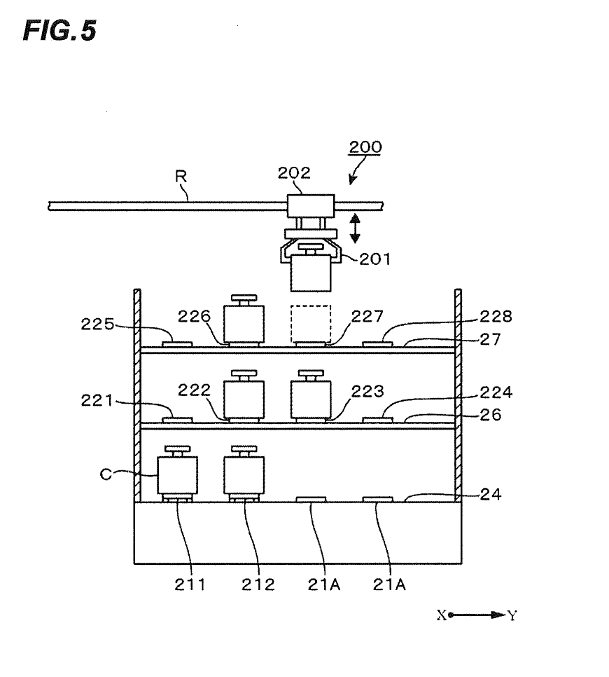

As shown in FIG. 5, a rail R extending in the Y direction of FIG. 5 is arranged on a top side of upper shelf 27. An external carrier transfer unit 200 is installed on rail R. The external carrier transfer unit 200 carries carrier C between the resist pattern forming apparatus and another external processing apparatus. The external carrier transfer unit 200 includes a holding unit 201 to hold carrier C. Holding unit 201 holds a lateral surface of carrier C from a left and right direction. Further, external carrier transfer unit 200 is movable among rail R and can ascend/descend so as to arrange carrier C on carrier loading-in units 225 and 226 of upper shelf 27 by an ascending/descending means 202 or to receive carrier C from carrier loading-out units 227 and 228.

Further, carrier block S1 includes carrier transfer unit 3 for transferring carrier C to each of arrangement unit 21 for transfer, arrangement unit 21A, and arrangement unit 22 for retraction of carrier station 2. Carrier transfer unit 3 is a multi-joint arm including, for example, a first arm 31, a second arm 32, and a holding arm 33, and is movable forward and backward, and is rotatable around a vertical axis by a rotation means 34.

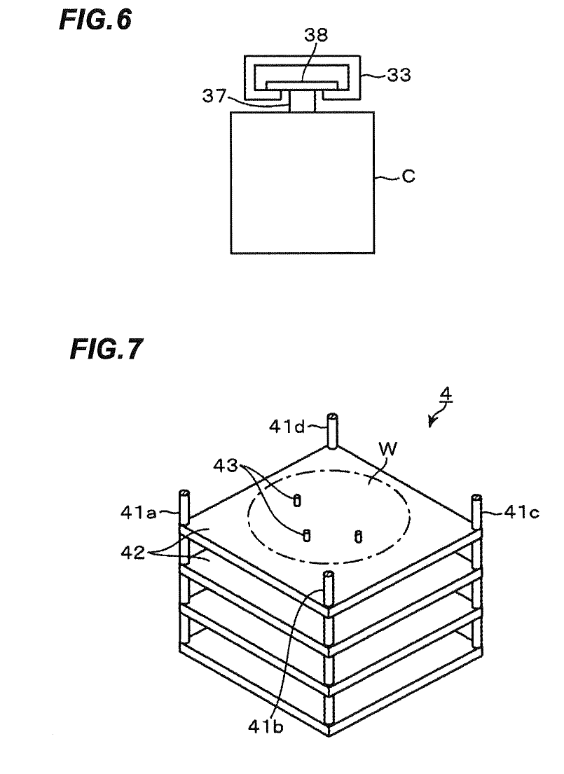

To describe the construction of carrier C, as shown in FIGS. 2 to 6, a plate shaped holding plate 38 is installed in the upper side of the carrier C by means of a support unit 37. Further, as shown in FIG. 6, holding arm 33 encloses a peripheral of holding plate 38 of the carrier C and supports the carrier C while the carrier C is hung.

Carrier transfer unit 3 can ascend/descend along an ascending/descending axis 35. Ascending/descending axis 35 is movable along a guide rail 36 (refer to FIG. 1). Guide rail 36 extends from a ceiling part of carrier block S1 in a Y direction of FIG. 1. Accordingly, carrier C can be transferred to each of arrangement unit 21 for transfer, arrangement unit 21A, and arrangement unit 22 for retraction of carrier station 2. Carrier transfer unit 3 stands by in a retraction region 30 when operation for transferring carrier C is not performed. As shown in FIG. 1, retraction region 30 is set in either of a left or right side of carrier station 2 when carrier station 2 is seen from a viewpoint of carrier transfer unit 3.

As shown in FIG. 3, arrangement unit 21 for transfer and arrangement units for retraction 225 to 228 include a location sensor 231 for identifying an arrangement location of carrier C and an existence sensor 232 for identifying the existence of carrier C, respectively. Arrangement units for retraction 221 to 224 in a middle stage and arrangement unit 21A include location sensors 231. Location sensor 231 or existence sensor 232 include a reflective optical sensor or a sensor detecting a movement of a striker. The striker is in contact with a bottom of carrier C and detects the location or existence of carrier C when carrier C is arranged on arrangement units 21, 21A, and 22.

As shown in FIGS. 1 to 4, substrate holding unit 4 and first substrate transfer unit A1 are installed between a rear surface wall 20 of carrier station 2 and processing block S2 in a backside region of the rear surface wall 20. Here, each installation location of substrate holding unit 4 and first substrate transfer unit A1 can be appropriately selected in a location where first substrate transfer unit A1 may access both carrier C arranged on arrangement unit 21 for transfer and substrate holding unit 4, and substrate holding unit 4 may access a second substrate transfer unit A2 installed in processing block S2 to be described later. However, in this case, first substrate transfer unit A1 is movably installed in an arrangement direction of the carrier in a location toward arrangement unit 21 for transfer. Substrate holding unit 4 is installed in an immediately lateral side of a movement region of first substrate transfer unit A1.

Referring to FIG. 4, first substrate transfer unit A1 includes a plurality of holding arms 5 for holding wafer W and a transfer base body 51. Transfer base body 51 supports holding arms 5 to be movable forward and backward. Transfer base body 51 can ascend/descend by a driving mechanism 52, is rotatable around a vertical axis, and is movable along an arrangement direction of carrier C (along a guide rail 53 extending in a Y direction of FIG. 4). Here, the number of holding arms 5 is set to a number equal to or less than the maximum number of wafers W received in carrier C. The number of holding arms 5 may have a divisor of the maximum number of wafers W. In this case, the maximum number of wafers W received in one carrier C is twenty five, so that the number of holding arms 5 is set to be 5.

Holding arms 5 (5a to 5e) are arranged in a multi-stage. The holding arms 5 are shaped like a rectangle so as to hold a center of a backside surface of wafer W, respectively. A front end of each of holding arms 5a to 5e is attached to an advance/retreat mechanism 55 by means of a holding member 54. In this case, among holding arms 5a to 5e, a third holding arm 5c that is the third from a top can individually advance along transfer base body 51, and the other holding arms 5a, 5b, 5d, and 5e except for third arm 5c can simultaneously advance. That is, a first advance/retreat mechanism 55a and a second advance/retreat mechanism 55b are installed such that they may advance/retreat forward and backward along transfer base body 51, respectively. First advance/retreat mechanism 55a moves third holding arm 5c forward and second advance/retreat mechanism 55b moves simultaneously four holding arms 5a, 5b, 5d, and 5e, except for third holding arm 5c forward. Accordingly, first substrate transfer unit A1 can perform a single transfer that carries a single wafer W by a single movement of first advance/retreat mechanism 55a and a collective transfer that simultaneously carries a plurality of wafers W, e.g. five wafers W, using both of first and second advance/retreat mechanisms 55a and 55b. Further, second advance/retreat mechanism 55b includes a mechanism for changing a pitch (an arrangement space in an upper/lower direction) of holding arms 5a, 5b, 5d, and 5e therein.

Next, substrate holding unit 4 will be described. Substrate holding unit 4 is configured to hold the maximum number of wafers W received in at least one carrier C in a shelf form. In the present example, substrate holding unit 4 holds 100 wafers W corresponding to four carriers in a multi-stage of a shelf form and transfers the wafers between first substrate transfer unit A1 and second substrate transfer unit A2 to be described later.

In the present example, as shown in FIGS. 4, 7, and 8, substrate holding unit 4 includes a stage 42 having a quadrangle shape installed in a multi-stage of a shelf form. A plurality of peripheral areas of stage 42 is supported by four supporting members 41a to 41d. Further, a plurality of protrusions 43, e.g. three protrusions 43 are installed on each stage 42 to hold a backside of wafer W. A size or an installation location of protrusion 43 and a space in an upper and lower direction between adjacent stages 42 are set so that holding arm 5 of first substrate transfer unit A1 and an arm unit of second substrate transfer unit A2 to be described later may advance/retreat in a lower side of wafer W supported by protrusion 43 and may advance/retreat in an upper side of protrusion 43 while holding wafer W in order not to interfere with protrusion 43.

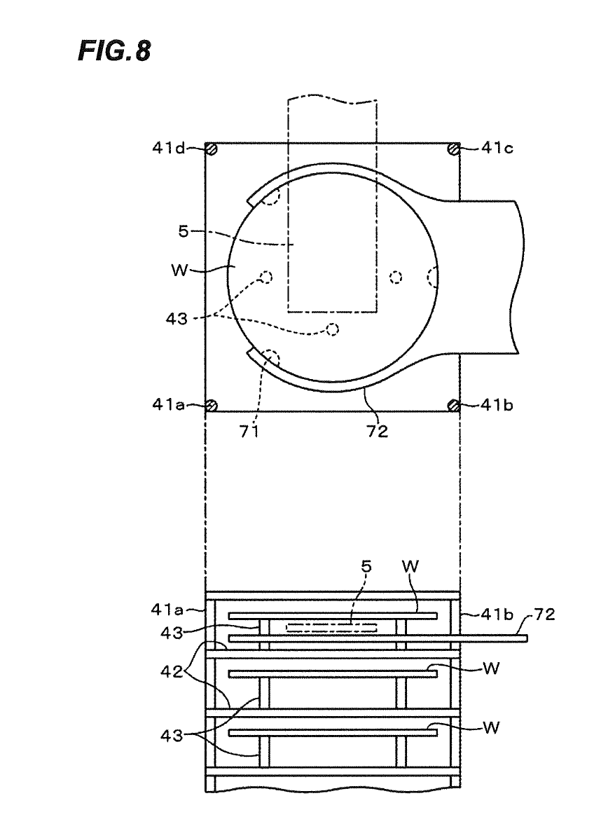

As shown in FIG. 8, holding arm 5 of first substrate transfer unit A1 is set to a size that allows holding arm 5 to advance/retreat between protrusions 43. Therefore, when wafer W is transferred from holding arm 5 to protrusion 43, holding arm 5 holding wafer W enters toward an upper side of protrusion 43 from a space between supporting members 41c and 41d and descends to transfer wafer W to protrusion 43, and then recedes in a lower side of protrusion 43. In the meantime, when holding arm 5 receives wafer W from protrusion 43, holding arm 5 enters toward a lower side of protrusion 43 from a space between supporting members 41c and 41d and ascends to receive wafer W on holding arm 5 from protrusion 43, and then recedes in a upper side of protrusion 43.

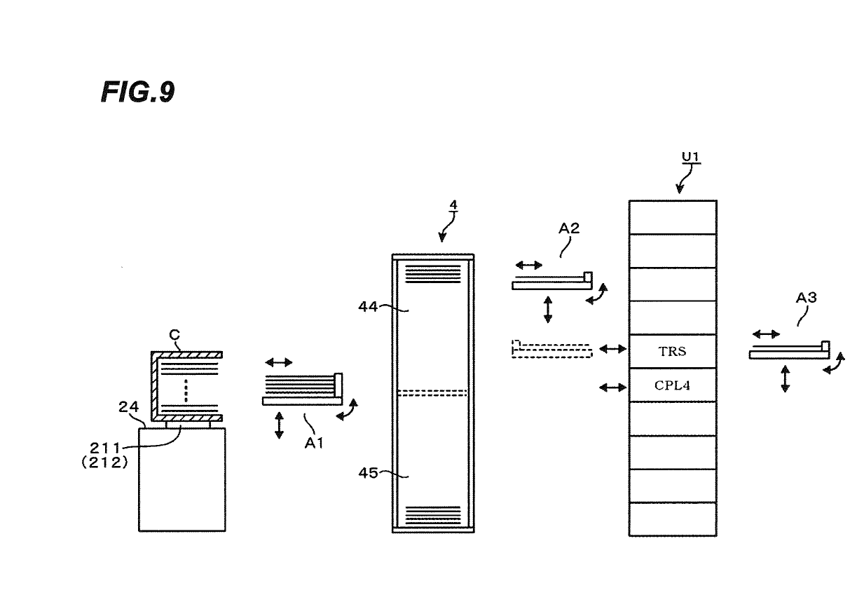

As shown in FIG. 9, in substrate holding unit 4, a upper fifty stages 42 among total one hundred stages 42 are assigned as a loading-in region 44. Wafer W loaded on processing block S2 is arranged on upper fifty stages 42. The other lower fifty stages 42 are assigned as a loading-out region 45. Wafer W loaded out from processing block S2 is arranged on the lower fifty stages 42.

Further, the number of stages 42 installed on substrate holding unit 4 must be larger than the maximum number of wafers W received in a single carrier C. However, the number of stages in loading-in region 44 and loading-out region 45 may be larger than the maximum number of wafers W received in one or more carriers, respectively, thereby performing the supply of wafer W to processing block S2 or the receipt of wafer W from processing block S2.

Processing block S2 is connected to an internal side of carrier block S1. Second substrate transfer unit A2, shelf modules U1 to U3, and main arms A3 and A4 are alternatively arranged in a sequence from a side of carrier block S1 in processing block S2. Shelf modules U1 to U3 have a multi staged modules of heating/cooling system. Main arms A3 and A4, i.e. a third substrate transfer unit, transfer wafer W between each module of shelf modules U1 to U3 and liquid processing modules U4 and U5 to be described later. That is, shelf modules U1, U2, and U3 and main arms A3 and A4 are arranged in a line from a side of carrier block S1. Each of the connected portions between the modules includes an opening for wafer transfer (not shown). Wafer W is freely movable from shelf module U1 in one end side of processing block S2 to shelf module U3 in the other end side of processing block S2.

Shelf modules U1 to U3 have the structure where various modules for performing a pre-processing and post-processing for processing, which are performed in liquid processing modules U4 and U5, are stacked in a multiple sages, e.g. 10 stages. Shelf modules U1 to U3 includes a transfer module TRS, a temperature control module CPL for controlling wafer W in a predetermined temperature, a heating module CLH for heating wafer W, a heating module CPH for heating wafer W after coating the resist liquid, a heating module PEB for heating wafer W prior to the developing processing, and a heating module POST for heating wafer after the developing processing.

Further, as shown in FIG. 2, liquid processing modules U4 and U5 have the structure where an antireflection film forming module BCT for coating a chemical liquid forming an antireflection film on wafer W, a coating module COT for coating the resist liquid on wafer W, and a developing module DEV for supplying a developing liquid to wafer W and performing the developing processing are stacked in a multiple stage, e.g. five stages.

An exposure apparatus S4 is connected to the inside of shelf module U3 in processing block S2 through a interface block S3. Interface block S3 includes a first transfer chamber 61 and a second transfer chamber 62 installed between processing block S2 and exposure apparatus S4 in a line. Interface block S3 includes a first transfer arm 63 and a second transfer arm 64 that can ascend/descend, rotate around a vertical axis, and advance/retreat. Further, shelf module U6 is installed in first transfer chamber 61. The transfer modules are stacked vertically in shelf module U6.

Main arms A3 and A4 transfer the wafer between every module (where wafer W is laid) within processing block S2, e.g. each module of shelf modules U1 to U3 and each module of liquid processing modules U4 and U5. Accordingly, the main arms are configured so as to advance/retreat, ascend/descend, rotate around a vertical axis, and move in a Y direction. Further, the main arms include two support arms for supporting an edge region of a circumference of a backside of wafer W. Two support arms can independently advance/retreat.

Second substrate transfer unit A2 can transfer wafer W between each stage 42 of substrate holding unit 4, and transfer module TRS or a temperature control module CPL4 installed in shelf module U1. Accordingly, as shown in FIGS. 1, 4, and 9, second substrate transfer unit A2 is installed adjacent to and between substrate holding unit 4 and shelf module U1 in an X direction of FIG. 1. As shown in FIGS. 4 and 8, an arm 72 includes holding protrusions 71 that hold an edge of a circumference of a backside of wafer W in second substrate transfer unit A2. Arm 72 is capable of advancing/retreating along a base 73. Base 73 can ascend/descend and rotate around a vertical axis by a driving mechanism 74.

Further, as shown in FIG. 8, when second substrate transfer unit A2 transfers wafer W from/to substrate holding unit 4, the shape or size of second substrate transfer unit A2 is set so that second substrate transfer unit A2 enters substrate holding unit 4 from an external side of protrusion 43. Therefore, when the wafer is transferred to protrusion 43, arm 72 holding wafer W on holding protrusions 71 enters on the upper side of protrusion 43 from the space between holding members 41b and 41c of substrate holding unit 4 and descends to transfer wafer W to protrusion 43, and recedes on the lower side of protrusion 43. Contrary to this, when the wafer is received from protrusion 43, arm 72 enters on the lower side of protrusion 43 from the space between holding members 41b and 41c and ascends to receive wafer W on holding protrusions 71 from protrusion 43, and recedes on the upper side of protrusion 43.

One example of the flow of wafer W in the resist pattern forming system is described. Wafer W within carrier C arranged on a wafer loading-in unit 211 of a carrier block S1 is transferred to loading-in region 44 of substrate holding unit 4 by first substrate transfer unit A1. Next, Wafer W within substrate holding unit 4 is transferred to transfer module TRS of shelf module U1 of processing block S2 by second substrate transfer unit A2. From transfer module TRS, wafer W is carried along a route starting from temperature control module CPL1 to antireflection film forming module BCT to heating module CLH to temperature control module CPL2 to coating module COT to heating module CPH to interface block S3 and ending at exposure apparatus S4, and then experiences an exposure processing in exposure apparatus S4. In the meantime, after the exposure processing, wafer W is returned to processing block S2 and is carried along a route from heating module PEB, temperature control module CPL3, developing module DEV, heating module POST, to temperature control module CPL4 of shelf module U1. Wafer W of temperature control module CPL4 is transferred to loading-out region 45 of substrate holding unit 4 by second substrate transfer unit A2. Wafer W is returned into original carrier C arranged on a wafer loading-out unit 212 of carrier block S1 from loading-out region 45 by first substrate transfer unit A1.

At this time, main arms A3 and A4 are controlled to perform a series of operations (a transfer cycle) of moving wafer W laid on each module from a downstream module to an upstream module one by one. Accordingly, main arms A3 and A4 receive the wafer from transfer module TRS of shelf module U1, and sequentially transfer the wafer to heating module CPH along the aforementioned transfer route in processing block S2. Next, main arms A3 and A4 receive exposure processed wafer W from interface block S3, and sequentially carries wafer W to temperature control module CPL4 along the aforementioned transfer route.

Further, the aforementioned resist pattern forming apparatus includes a controller 8. Controller 8 includes a computer that manages a recipe of each processing module or a transfer flow (transfer route) of wafer W and controls processing of each processing module or driving of external carrier transfer unit 200, carrier transfer unit 3, first substrate transfer unit A1, second substrate transfer unit A2, and main arms A3 and A4. Controller 8 includes, for example, program storage unit that stores a computer program. The software includes a step (instruction) group for executing the entire operation of the resist pattern forming apparatus, i.e. for executing the processing in each module or the transfer of wafer W to form a certain resist pattern on wafer W. Further, controller 8 reads the program, so that the entire operation of the resist pattern forming apparatus is controlled by controller 8. Further, the program is stored in memory medium, such as a flexible disk, hard disk, compact disk, optical-magnetic disk, or a memory card.

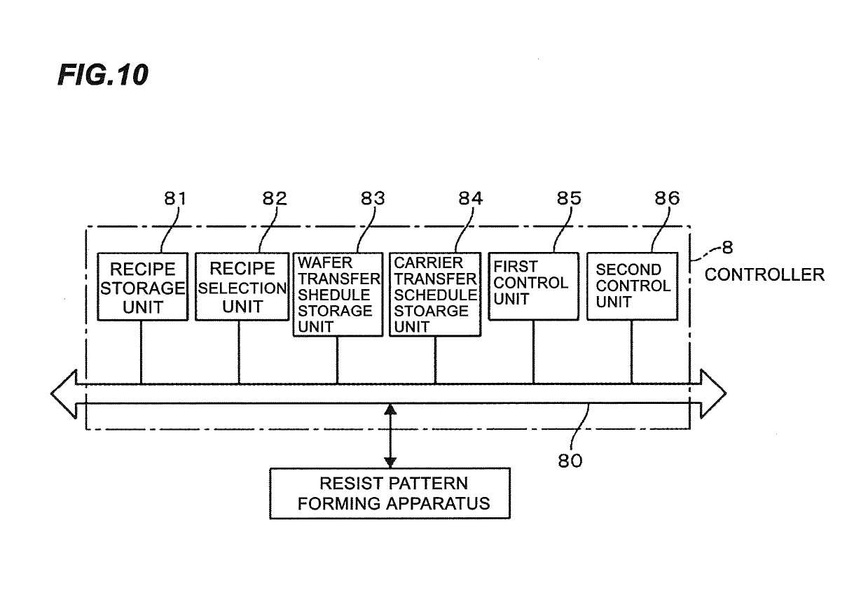

FIG. 10 illustrates the structure of the controller. The controller actually includes a CPU (Central Processing Unit), a program, and memory. However, the present disclosure is characterized in transferring the carrier in carrier station 2 and transferring wafer W within the carrier to processing block S2. Therefore, a portion of the structural elements related to the characteristic are explained by blocks. Reference number 80 denotes a bus and bus 80 is connected with a recipe storage unit 81, a recipe selection unit 82, a wafer transfer schedule storage unit 83, a carrier transfer schedule storage unit 84, a first control unit 85, and a second control unit 86.

For example, recipe storage unit 81 stores a transfer recipe recording the transfer route of wafer W or a plurality of recipes recording a processing condition for wafer W. Wafer transfer schedule storage unit 83 is a means to store a schedule. The schedule includes the contents of at which timing every wafer within a lot being carried to which module based on the transfer recipe, e.g. a transfer schedule. In the transfer schedule, a sequence is assigned to the wafer and transfer cycle data determining a transfer cycle by calibrating the sequence of the wafer to each module are arranged in a time series.

Carrier transfer schedule storage unit 84 is a means to store a transfer schedule of carrier C in carrier station 2. Here, an address is assigned to arrangement unit 21 for transfer and arrangement unit 22 for retraction, respectively. A unique ID is assigned to each of carriers C. Accordingly, the transfer schedule describes in a time series that which carrier C is transferred to which arrangement units 21 and 22 at which timing by corresponding carrier C to arrangement unit 21 for transfer and arrangement unit 22 for retraction in a time series.

First control unit 85 is a means to control first substrate transfer unit A1 or second substrate transfer unit A2 when wafer W is transferred from carrier C through substrate holding unit 4 to processing block S2. Further, second control unit 86 is a means to control carrier transfer unit 3, first substrate transfer unit A1, second substrate transfer unit A2, and main arms A3 and A4. Second control unit 86 executes a predetermined transfer operation with reference to the wafer transfer schedule or the carrier transfer schedule.

Next, the operation of the present embodiment will be described. Prior to describing the processing for wafer W, that is, the substrate, the operator selects the lot to be processed, the processing recipe, the wafer transfer schedule, and the carrier transfer schedule. Accordingly, the processing sequence of the lot is determined, and in accordance with the processing sequence, carrier C is arranged on arrangement unit 211 for transfer (the wafer loading-in unit). With respect to a lot L1 to a lot L5, this example will describe the case where the processing is performed in a sequence from lot L1, lot L2, lot L3, lot L4, to lot L5. In this case, the carrier is given for every lot. Therefore, the processing sequence of the lot corresponds to a sequence of loading the carrier corresponding to the lot in carrier loading-in units 225 and 226, and a sequence of loading the carrier in wafer loading-in unit 211 as well.

Therefore, the carrier is sequentially loaded in carrier loading-in units 225 and 226 in a sequence from carrier C1 of lot L1, carrier C2 of lot L2, carrier C3 of lot L3, carrier C4 of lot L4, to carrier C5 of lot L5 by external carrier transfer unit 200 in carrier block S1. Then, carriers C1 to C5 are sequentially transferred by carrier transfer unit 3 in a sequence starting from carrier C1 to carrier C2 to carrier C3 to carrier C4 and ending to carrier C5 directly or through other arrangement unit 22 for retraction within stocker 25 according to the transfer schedule. At this time, the transfer schedule is written so that vacant carrier C of which wafer W has been taken out is transferred to arrangement unit 22 for retraction and a next carrier is loaded in wafer loading-in unit 211.

Next, the exemplary procedure of transferring wafer W within carrier C to processing block S2 will be described. In this example, twenty five wafers W1 are received in carrier C1, one wafer W2 is received in carrier C2, twenty five wafers W3 are received in carrier C3, one wafer W4 is received in carrier C4, and twenty five wafers W5 are received in carrier C5.

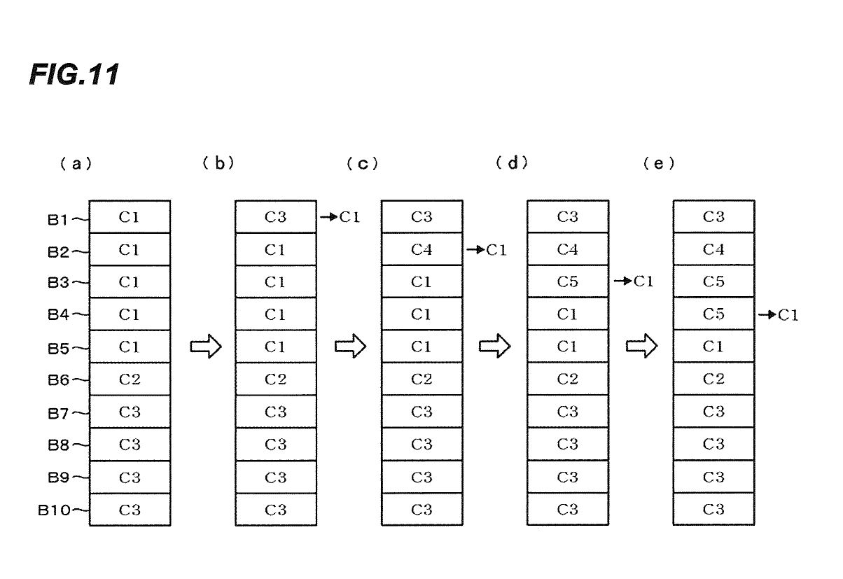

In this example, prior to second substrate transfer unit A2's transfer, the wafer within the carrier is transferred to loading-in region 44 by first substrate transfer unit A1 so as to fill all of fifty stages 42 of loading-in region 44 of substrate holding unit 4. In this case, first substrate transfer unit A1 simultaneously accesses five stages 42 by five holding arms 5. Therefore, as shown in FIG. 11A, loading-in region 44 is divided into 10 blocks of blocks B1 to B10 from a top side for every five stages 42, and first substrate transfer unit A1 accesses every block to simultaneously transfer five wafers W. That is, when first substrate transfer unit A1 transfers wafer W1 within carrier C1, first substrate transfer unit A1 simultaneously receives five wafers W1 from the upper side within carrier C1 by five holding arms 5 and simultaneously transfers received wafers W1 to five stages 42 of block B1 of loading-in region 44. Therefore, twenty five wafers W1 of carrier C1 are transferred to blocks B1 to B5 of loading-in region 44.

Next, first substrate transfer unit A1 receives one wafer W2 within carrier C2 by third holding arm 5c of first substrate transfer unit A1, and then transfers wafer W2 to a block B6 of loading-in region 44. Accordingly, if the number of wafers W2 is one, wafer W2 is transferred to the topmost stage 42 of block B6 by third holding arm 5c. Next, twenty five wafers W3 within carrier C3 are transferred to loading-in region 44 by first substrate transfer unit A1. At this time, there is a space only for 4 blocks B7 to B10, i.e. for twenty stages 42, so that twenty wafers W3 out of wafers W3 received in carrier C3 are transferred to blocks B7 to B10.

In this way, first substrate transfer unit A1 transfers wafer W to total fifty stages 42 of loading-in region in substrate holding unit 4. Thereafter, as shown in FIG. 11B, wafer W is sequentially received one by one from upper block B1 of loading-in region 44, and is transferred to transfer module IRS of shelf module U1 of processing block S2 by second substrate transfer unit A2. Further, if every wafer W of block B1 is transferred to processing block S2, remaining five wafers W3 of carrier C3 are transferred to vacant block B1 by first substrate transfer unit A1.

Next, as shown in FIG. 11C, second substrate transfer unit A2 transfers wafer W2 from block B2 of loading-in region 44 to transfer module TRS of processing block S2, and then, one wafer W4 is transferred from next carrier C4 to vacant block B2 by first substrate transfer unit A1. Wafer W5 is also transferred for carrier C5 (refer to FIGS. 11D and 11E).

In this way, the carrier is transferred to wafer loading-in unit 211 in a sequence starting from carrier C1 to carrier C2 to carrier C3 to carrier C4 and ending to carrier C5. Further, carrier transfer unit 3 is controlled so that vacant carrier C of which wafer W has been taken out is transferred to arrangement unit 22 for retraction and the new carrier receiving next non-processed wafer W is loaded in wafer loading-in unit 211.

Further, first substrate transfer unit A1 and second substrate transfer unit A2 are controlled by a transfer controller 65 so that five wafers W within the carrier arranged in wafer loading-in unit 211 are transferred to loading-in region 44 of substrate holding unit 4 by first substrate transfer unit A1 at a same time or one by one and the wafer within loading-in region 44 is transferred one by one to processing block S2 by second substrate transfer unit A2. At this time, in loading-in region 44 of substrate holding unit 4, four vacant stages 42 exist between wafer W2 of carrier C2 and the head of wafer W3 in carrier C3, but transfer controller 65 has already recognized that which stage 42 of loading-in region 44 is vacant, so that it controls second substrate transfer unit A2 to access stage 42 on which wafer W2 is arranged and then stage 42 on which wafer W3 is arranged.

In the meantime, in processing block S2, wafer W is carried to a predetermined module by main arms A3 and A4 in a sequence of wafer W being transferred to transfer module TRS by second substrate transfer unit A2, i.e. from W1 of carrier C1, according to the wafer transfer schedule. Then, processing-completed wafer W1 of carrier C1 is sequentially transferred from upper stage 42 to loading-out region 45 of substrate holding unit 4 one by one by second substrate transfer unit A2. Five wafers W1 within loading-out region 45 are collectively returned to original carrier C1 laid on wafer loading-out unit 212 by first substrate transfer unit A1.

At this time, a block is assigned for every five stages 42 in loading-out region 45 of substrate holding unit 4. For example, if wafer W1 is transferred to every stage of a single block by second substrate transfer unit A2, transfer control unit 65 controls such that five holding arms receive five wafers W at the same time and wafers W are transferred to original carrier C1 of wafer loading-out unit 212. In the meantime, carrier transfer unit 3 is controlled such that it transfers original carrier C1 corresponding to a lot to wafer loading-out unit 212 by the time first substrate transfer unit A1 receives the head of processing-completed wafer W1 in the lot held in loading-out region 45. Such a control is performed by writing the wafer transfer schedule as in above description. Accordingly, carrier C1 is transferred by carrier transfer unit 3 along the route starting from wafer loading-in unit 211 to arrangement unit 22 for retraction and ending to wafer loading-out unit 212 according to the wafer transfer schedule within carrier station 2. In the same manner, wafers W of carriers C2 to C5 after completion of processing are sequentially returned to original carriers C2 to C5 that are transferred to wafer loading-out unit 212.

Since the number of wafer W2 (W4) of carrier C2 (C4) is one, if wafer W2 (W4) is transferred to one block of loading-out region 45 by second substrate transfer unit A2, transfer controller 65 controls first substrate transfer unit A1 to receive wafer W2 (W4) from the block, and transfer controller 65 controls carrier transfer unit 3 to transfer original carrier C2 (C4) to wafer loading-out unit 212 by the time first substrate transfer unit A1 receives wafer W2 (W4) of loading-out region.

Further, as described above, in case where loading-in region 44 and loading-out region 45 of substrate holding unit 4 are divided into a block having as many stages as the number of holding arms 5 and holding arms 5 access for every block to transfer wafer W, first substrate transfer unit A1 may have the structure in which five holding arms 5 always advances/retreats at the same time.

Further, as described above, in case where first substrate transfer unit A1 having the structure of performing the collective transfer by five holding arms 5a to 5e and the single transfer by one holding arm 5c is used, loading-in region 44 and loading-out region 45 of substrate holding unit 4 are not divided into blocks, and five holding arms or one holding arm may transfer wafer W to the stage of loading-in region 44 or loading-out region 45 in sequence from the top.

According to the embodiment, stocker 25 temporarily storing carrier C is installed in carrier station 2, the plurality of carrier C arrangement units are arranged on stocker 25, carrier C arrangement units are also used as arrangement units 22 for retraction for retracting carrier C, substrate holding unit 4 for holding the maximum number of wafers W received in at least one carrier in the shelf form is provided, the plurality of wafers are collectively transferred from carrier C to substrate holding unit 4 by first substrate transfer unit A1, and then wafers W are transferred from substrate holding unit 4 to processing block S2 one by one by second substrate transfer unit A2. Accordingly, wafer W can be smoothly supplied from carrier C to processing S2.

That is, as described above, the plurality of wafers W are transferred to substrate holding unit 4 at a time, but wafers W are extracted from substrate holding unit 4 one by one. Therefore, even if one wafer loading-in unit 211 is included like the present disclosure, when the carrier of which wafer W has been already taken out is retracted to arrangement unit 22 for retraction and then the new carrier which receives non-processed substrates is arranged, wafer W is held in substrate holding unit 4.

Therefore, even if first substrate transfer unit A1 cannot take wafer W out of carrier C, wafer W is held in substrate holding unit 4. Accordingly, wafer W can be continuously supplied from carrier C to processing block S2 without interruption, in comparison with the case of transferring wafers W one by one from carrier C to processing block S2. Further, even if the supply is interrupted, the interruption time can decrease. Accordingly, wafer W can be rapidly supplied from carrier C to processing block S2. Therefore, it is possible to prevent the deterioration of the operating rate of processing module of processing block S2 and exposure apparatus S4, thereby improving the throughput.

Further, the transfer route according to the wafer transfer schedule is started by transferring non-processed wafer W to processing block S2 (transfer module TRS) by second substrate transfer unit A2 and is finished by receiving processing-completed wafer W from processing bock S2 (temperature control module CPL4) by second substrate transfer unit A2. Accordingly, second substrate transfer unit A2 is associated with main arms A3 and A4 to transfer wafer W. However, first substrate transfer unit A1 is not associated with the transfer of second substrate transfer unit A2 and main arms A3 and A4, but separately transfers wafer W. Further, first substrate transfer unit A1 can simultaneously transfer five wafers W by five holding arms 5. Accordingly, the transfer capability increase in comparison with the transfer of the wafers W one by one, thereby the time required for wafer transfer between the carrier and substrate holding unit 4 decreases. Therefore, even though the throughput of processing block S2 is further improved later, it is possible to supply wafer W from substrate holding unit 4 to processing block S2 in response to the improved throughput, thereby the throughput can be much greater improved.

Further, as described in the above, when wafer W is transferred from carrier C by first substrate transfer unit A1 so as to fill every stage 42 of loading-in region 44 of substrate holding unit 4 in advance, and wafer W is transferred to processing block S2 by second substrate transfer unit A2, even if the carrier is often exchanged, e.g. the carrier receiving only one wafer is continuously carried to wafer loading-in unit 211, wafer W can be continuously supplied from carrier C to processing block S2 without interruption because the plurality of wafers W are mounted on substrate holding unit 4 in advance. As a result, the deterioration of capacity of the processing module can be stopped.

Further, carrier transfer unit 3 transfers the original carrier corresponding to a lot to wafer loading-out unit 212 by the time first substrate transfer unit A1 receives the head of processing-completed wafers W in the lot held by substrate holding unit 4. Accordingly, when processing-completed wafer W is returned to original carrier C, there is no interruption in transferring the wafer, thereby improving the throughput more.

Further, according to the aforementioned embodiment, even if the number of wafer loading-in unit 211 and wafer loading-out unit 212 is one, respectively, wafer W can be smoothly transferred from substrate holding unit 4 to processing block S2 as described above, Therefore, first substrate transfer unit A1 accesses only two carriers, thereby decreasing the movement distance in the carrier arrangement direction (Y direction). Accordingly, because it is efficient in a spatial viewpoint and the movement distance decreases, the time for transferring wafer W between the carrier and substrate holding unit 4 decreases.

Further, the number of holding arms 5 in first substrate transfer unit A1 is set as a divisor of the maximum number of wafers W received in the carrier. Accordingly, when the maximum number of wafers W is received in the carrier, if holding arm 5 accesses the carrier multiple times, all of wafers W can be transferred without any wafer W being remained.

Further, first substrate transfer unit A1 is constructed to be capable of performing the single transfer of one wafer W using only one holding arm and the collective transfer of five wafers W using five holding arms. Accordingly, as described above, even if one wafer W is received in the carrier, only the one wafer W can be transferred to substrate holding unit 4 by one holding arm. Further, as described in the above, if substrate holding unit 4 is not divided into the block having the number of stages corresponding to the number of holding arms, the wafer is transferred to fill the stages in a sequence from the upper stage. Therefore, additional vacant stage 42 does not need to be formed in substrate holding unit 4.

Further, if substrate holding unit 4 is divided into blocks, first substrate transfer unit A1 accesses every block and transfers wafer W. Accordingly, it is easy to control the movement of first substrate transfer unit A1. That is, because a block corresponds to a carrier, it is clear that the wafer of which carrier is transferred to which block. Therefore, first substrate transfer unit A1 or second substrate transfer unit A2 can be easily controlled by transfer controller 65.

At this time, because the number of stages in one block corresponds to the number of holding arms, the number of holding arms 5 is preferably set to the divisor of the maximum number of wafers W received in the carrier. That is, the number of stages of substrate holding unit 4 is set on a basis of the maximum number of wafers W received in the carrier. Accordingly, if the number of the substrate holding unit is set to a multiple, e.g. 4, of the maximum number of wafers W, first substrate transfer unit A1 can access all of stages 42 by accessing several times. Further, since the number of stages in one block corresponds to the number of holding arms, it is possible to divide substrate holding unit 4 into small size of blocks. When the number of wafers within the carrier is identical to or less than the number of holding arms, even if first substrate transfer unit A1 accesses every block, it is possible to transfer wafers W received in more number of carriers to substrate holding unit 4 because it is not necessary to form additional vacant stage 42 in substrate holding unit 4.

With respect to the number of holding arms of first substrate transfer unit A1, it may be set to the identical number to the maximum number of wafers W received in one carrier. In this case, because wafers W within the carrier can be transferred to substrate holding unit 4 at a time, if the maximum number of wafers W is received in the carrier, the transfer time decreases. Further, because the number of accesses to the carrier or substrate holding unit 4 decreases, there is an advantage of prohibiting the occurrence of particle and improving the durability of first substrate transfer unit A1.

In the above description, wafer W is not necessary to be transferred to every stage 42 of loading-in region 44 of substrate holding unit 4 in advance in the present disclosure. For example, when wafers W within the carrier are simultaneously received and simultaneously transferred to loading-in region 44 of substrate holding unit 4 by the plurality of holding arms, second substrate transfer unit A2 may move to loading-in region 44 to receive wafer W.

In this case, the plurality of wafers W is transferred from carrier C to substrate holding unit 4 at a time, but wafers W are extracted from substrate holding unit 4 one by one. Accordingly, even when the vacant carrier of which wafer W has been taken out is exchanged with the new carrier receiving the non-processed substrate, wafer W is held in substrate holding unit 4. Therefore, it is possible to supply wafer W to processing block S2 without interruption. Further, even if the supply of wafer W is interrupted, the interruption time is short.

Further, the collective transfer of the plurality of wafers W from the carrier to substrate holding unit 4 by first substrate transfer unit A1 and the single transfer of wafers W one by one from substrate holding unit 4 to processing block S2 by second substrate transfer unit A2 are not limited to the aforementioned embodiment. For example, the transfer of wafer W within the carrier may start after securing the vacant space capable of transferring all wafers W received in carrier C to the stage of substrate holding unit 4.

Further, if first substrate transfer unit A1 has the structure in which the plurality of wafers W are collectively carried between carrier C and substrate holding unit 4, it is not limited to the above embodiment. Further, if substrate holding unit 4 has the structure allowing first substrate transfer unit A1 and second substrate transfer unit A2 to access to substrate holding unit 4, it is not limited to the above embodiment. The structure or layout of first substrate transfer unit A1, substrate holding unit 4, and second substrate transfer unit A2 can be appropriately selected.

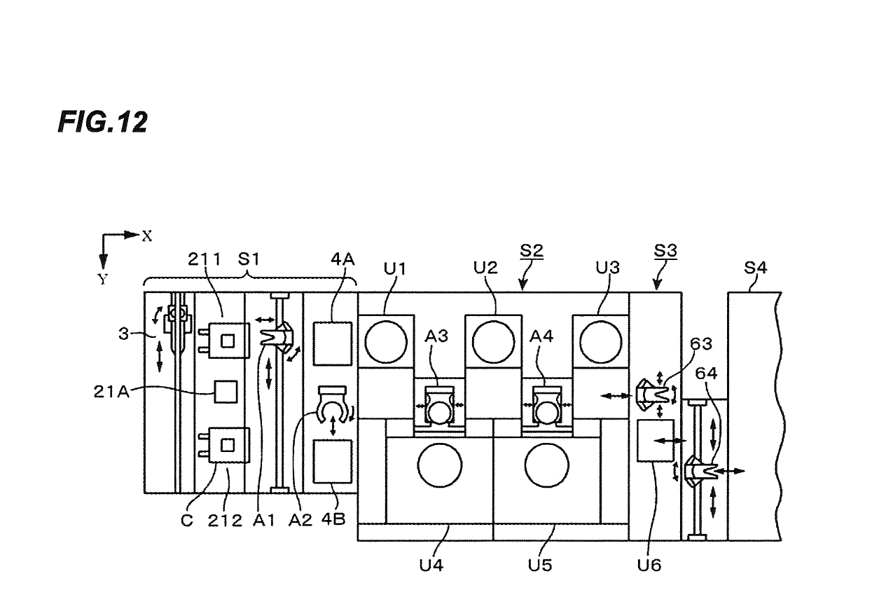

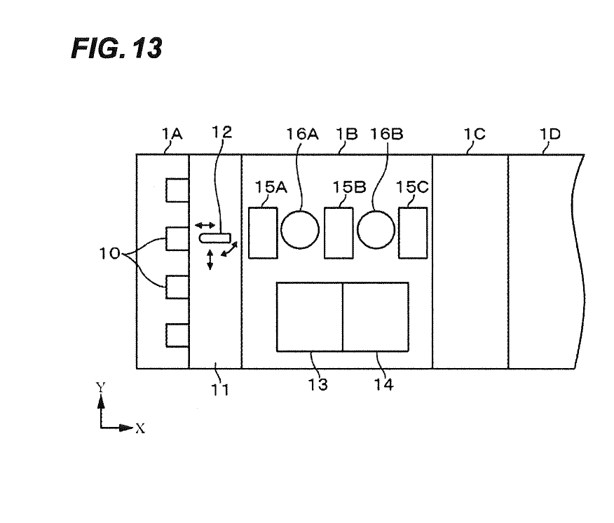

Further, as shown in FIG. 12, a substrate holding unit 4A including only loading-in region 44 and a substrate holding unit 4B including only loading-out region 44 may be separately installed in substrate holding unit 4. First substrate transfer unit A1 may be installed to be capable of advancing/retreating, ascending/descending, rotating around a vertical axis, and moving in the Y direction of FIG. 12 so as to access substrate holding units 4A and 4B. In this example, second substrate transfer unit A2 is installed between two substrate holding units 4A and 4B in carrier block S1. Second substrate transfer unit A2 can advance/retreat, ascend/descend, rotate around a vertical axis so as to transfer wafer W between transfer module TRS and temperature control module CPL4 of shelf module U1 in substrate holding units 4A and 4B and processing block S2. The structure of installing second substrate transfer unit A2 in carrier block S1 has an advantage in that it is not required to change the layout of the conventional processing block.

The present disclosure can be applied to the resist pattern forming apparatus that processes the substrate, such as a glass substrate (LCD substrate) for liquid crystal display, as well as the semiconductor wafer. Further, the shape of carrier transfer unit 3 is not limited to the aforementioned structure. Further, the structure of the storage unit (stocker) for temporarily storing the carrier is not limited to the aforementioned one. The arrangement unit for carrier may be installed on a lower side of arrangement stage 24 or may be installed to face arrangement stage 24. Further, with reference to the arrangement unit of the storage unit, a carrier C receiving non-processed wafer W, a carrier receiving processing-completed wafer W, or a vacant carrier is temporarily stored in the arrangement unit of the storage unit. In addition, it is not necessary to use every arrangement units as the arrangement unit for retraction.

Further, the arrangement unit for transfer may serves both as an arrangement unit used in transferring wafer W from carrier block S1 to processing block S2 and the arrangement unit used in returning wafer W from processing block S2 to carrier block S1. The number of arrangement units for transfer which first substrate transfer unit A1 accesses is appropriately selected.

Further, the present disclosure can be applied to a type of a substrate processing apparatus which includes a plurality of processing modules for performing the same processing in a processing block and transfers wafers W of the substrate holding unit to the processing modules in parallel by third substrate transfer unit A3. Also, the present disclosure can be applied to a type of a substrate processing apparatus which includes a plurality of processing modules for performing a different processing in a processing block and transfers wafer W to the different processing modules one by one by second substrate transfer unit according to the processing sequence.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising a carrier receiving a plurality of substrates and an arrangement unit for transfer given for every carrier, the substrate processing apparatus processing substrates taken out of the carrier arranged on the arrangement unit for transfer one by one in a processing block, and then returning the substrates to an original carrier on the arrangement unit for transfer, the substrate processing apparatus comprising:
a plurality of arrangement units for retraction to arrange the carrier, separately installed from the arrangement unit for transfer;
a carrier transfer unit to transfer the carrier of which the substrates is taken out in the arrangement unit for transfer to the arrangement unit for retraction, and transfer a new carrier receiving non-processed substrates to the arrangement unit for transfer;
a substrate holding unit to hold a maximum number of substrates received by at least one carrier in a shelf form;
a first substrate transfer unit comprising a plurality of holding arms to hold the substrates so as to collectively receive a plurality of substrates from the carrier arranged on the arrangement unit for transfer and transfer the substrates to the substrate holding unit; and
a second substrate transfer unit to receive the substrates from the substrate holding unit one by one and transfer the received substrate to the processing block.

2. The substrate processing apparatus of claim 1, the number of the arrangement unit for transfer is plural.

3. The substrate processing apparatus of claim 1, wherein the substrate holding unit holds a processing-completed substrates after a processing in the processing block, the second substrate transfer unit receives the processing-completed substrate one by one from the processing block to transfer the received substrate to the substrate holding unit,
the first substrate transfer unit collectively receives the plurality of processing-completed substrates from the substrate holding unit to transfer the collectively received processing-completed substrates to the original carrier on the arrangement unit for transfer, and
the carrier transfer unit transfers the original carrier corresponding to a lot to the arrangement unit for transfer by the time the first substrate transfer unit receives the head of processing-completed substrates in the lot held in the substrate holding unit.

4. The substrate processing apparatus of claim 3, wherein the substrate holding unit holds the non-processed substrate and holds the processing-completed substrate after processing in the processing block.

5. The substrate processing apparatus of claim 1, wherein the substrate holding unit holds the substrates equal to or more than two times of a maximum number of the substrate received in one carrier.

6. The substrate processing apparatus of claim 1, wherein in the first substrate transfer unit, a number of holding arms is a divisor of a maximum number of substrates received in the carrier.

7. The substrate processing apparatus of claim 1, wherein the first substrate transfer unit comprises a first advance/retreat mechanism to advance/retreat one holding arm only and a second advance/retreat mechanism to collectively advance/retreat remaining holding arms.

8. The substrate processing apparatus of claim 1, wherein the processing block comprises a plurality of modules and a third substrate transfer unit so as to form a coating film on the substrate and develop the substrate after exposure, the plurality of modules processing the substrate or disposing the substrate thereon, and the third substrate transfer unit transferring the substrate between the plurality of modules.
